(19) United States
(12) Patent Application Publication
(10) Pub. No.: US 2014/0174506 A1
(43) Pub. Date: Jun. 26, 2014

(54) UNITARY SOLAR ROOF AND GLASS STRUCTURE

(71) Applicant: Hyundai Motor Company, Seoul (KR)

(72) Inventors: Won Jung Kim, Seoul (KR); Sung Geun Park, Chuncheon (KR); Hae Yoon Jung, Seoul (KR); Sang Hak Kim, Seoul (KR); Ji Yong Lee, Suwon (KR); Mi Yeon Song, Seoul (KR); Ki Chun Lee, Seoul (KR); Eun Young Lee, Seoul (KR)

(73) Assignee: HYUNDAI MOTOR COMPANY, Seoul (KR)

(21) Appl. No.: 13/900,801

(22) Filed: May 23, 2013

(30) Foreign Application Priority Data
Dec. 21, 2012 (KR) 10-2012-0150737

(51) Int. Cl. H01L 31/048

(52) U.S. Cl. CPC H01L 31/0488
USPC 136/251

(57) ABSTRACT

Disclosed is a solar roof structure unified with glass, more particularly a solar roof structure unified with glass having transparency at a part where viewing therethrough is required and having a dye-sensitized solar cell panel equipped inside a transparent support, thus being applicable as a power source while ensuring viewability therethrough, and hence being applicable to, for example, an automotive sunroof.

### CROSS-REFERENCE TO RELATED APPLICATIONS

This application claims priority under 35 U.S.C. §119 to Korean Patent Application No. 10-2012-0150737, filed on Dec. 21, 2012, in the Korean Intellectual Property Office, the disclosure of which is incorporated herein by reference in its entirety.

### BACKGROUND

(a) Technical Field

The present invention relates to a solar roof and glass structure, particularly wherein the solar roof structure is unified with glass. More particularly, the present invention provides a unitary solar roof and glass structure having transparency at one or more portions through which viewing is required and having a dye-sensitized solar cell panel equipped inside a transparent support. As such, the structure is applicable as a power source while allowing viewing therethrough, thus being applicable to an automotive sunroof and the like.

(b) Background Art

Recently, with growing concerns and interests in environment-friendly sources of energy, the development of a silicon solar cell panel installed on the roof of a vehicle to generate electrical power during outdoor parking and vehicle use has been studied. For example, such generated electrical power could suitably be used for air conditioning, battery recharging, etc.

Although currently commercialized silicon solar cells exhibit higher photoelectric conversion efficiency than other types of solar cells, they may only be used for hybrid electric vehicles (HEVs), electric vehicles (EVs) or limited models of high-end vehicles due to low power generation efficiency when indoors or on cloudy days. Further, such solar cells are heavy weight, opaque and expensive.

Accordingly, the development of a next-generation solar cell capable of overcoming these disadvantages is necessary. In particular, dye-sensitized solar cells are drawing a lot of attentions since such cells can generate electrical power indoors or in the dark. While the photoelectric conversion efficiency of such cells is lower than that of silicon solar cell, fabrication costs are only about ⅓ the fabrication costs of silicon solar cells. Further, dye-sensitized solar cells can possess various colors.

However, since the dye-sensitized solar cell usually uses a thick glass panel, it results in increased weight when installed on the vehicle body or windowpane. Application of such a solar cell, thus, may require a change in design of the vehicle due to the large thickness. Therefore, the development of a light and thin solar cell for a vehicle is necessary.

US Patent Application Publication No. 2008-99064 describes a solar cell module including an encapsulant layer, Korean Patent No. 10-442503 describes a dye-sensitized solar cell for a sunroof and Japanese Patent Publication No. 2005-67472 describes a sunroof apparatus using a dye-sensitized solar cell. In addition, the inventors of the present invention have disclosed use of a polymer material, such as polyethylene, polypropylene, polyacryl, etc., for a transparent film to prevent scattering of broken pieces of glass in Korean Patent Application Publication No. 2012-43593.

However, these existing techniques are unlikely to be applicable to practical use and fail to satisfy safety and functional requirements for integrated parts for use in, for example, automotive sunroofs.

In attempt to solve this problem, Korean Patent No. 10-711566 describes a method for adhering a silicon solar cell onto an automotive sunroof, wherein an EVA sheet, a backsheet, etc., are compressed to fabricate a solar cell module for an automotive sunroof. In this patent, in order to ensure tight adhesion of the solar cell to the curved sunroof glass, the curvature area of the curved sunroof glass is calculated and the solar cell is adhered to the curved sunroof glass after it is cut into several pieces. The solar cell module is then fabricated by sequentially arranging a lower EVA film, the solar cell, an upper EVA film and a backsheet and then compressing using a laminator. Although this method is improved over the previous method, there are disadvantages of structural defects, opacity and high cost.

Throughout the specification, a number of publications and patent documents are referred to and cited. The disclosure of the cited publications and patent documents is incorporated herein by reference in its entirety to more clearly describe the state of the related art and the present invention.

### SUMMARY

The inventors of the present invention have found that, if a solar cell panel is laminated between thin and lightweight transparent supports using a bonding material or an adhesive member, the resulting unified solar roof structure has openness (ability to see therethrough) and safety, is capable of preventing scattering of pieces if the solar cell panel is broken, and is further lightweight and thin.

Accordingly, the present invention provides a light and thin high-quality solar roof structure that is unified with glass and that exhibits openness (ability to see therethrough) and safety.

In an aspect, the present invention provides a solar roof structure unified with glass in which a solar cell is built in a solar roof, including: a first and a second support formed of a transparent reinforced glass or a transparent polymer material; a solar cell, such as a dye-sensitized solar cell panel, a organic photovoltaic cell, a crystalline silicon solar cell, an amorphous silicon solar cell, and a thin film solar cell, disposed between the first and second supports; and a bonding material layer for bonding and unifying the first and second supports with the solar cell panel disposed between the first support and the second support.

Other features and aspects of the present invention will be apparent from the following detailed description, drawings and claims.

### BRIEF DESCRIPTION OF THE DRAWINGS

The above and other objects, features and advantages of the present invention will now be described in detail with reference to certain exemplary embodiments thereof illustrated in the accompanying drawings which are given hereinbelow by way of illustration only, and thus are not limitative of the invention.

FIG. 1 shows an exemplary general structure of a dye-sensitized solar cell panel that can be applied to an embodiment of the present invention, wherein (a) shows a parallel structure and (b) shows a monolithic structure.

FIG. 2 shows exemplary embodiments according to the present invention, wherein (a) shows a solar cell panel inserted between first and second supports and unified by a bonding material layer disposed on at least one of the first and second supports, and (b) and (c) show further examples having an adhesive member layer.

FIG. 3 shows further exemplary embodiments according to the present invention, wherein (a)-(f) show various examples wherein a solar cell panel is inserted in a first support having an insertion hole and unified by a bonding material layer disposed on the first support or between the solar cell panel and a second support and, optionally, an adhesive member layer.

FIG. 4 shows further exemplary embodiments according to the present invention, wherein (a)-(d) show various examples wherein a solar cell panel is inserted between a first support and a second support, each having an insertion hole, and unified by a bonding material layer disposed on the first support or between the solar cell panel and a second support and, optionally, an adhesive member layer.

FIG. 5 shows further exemplary embodiments according to the present invention, wherein (a)-(c) show various examples wherein a protective coating layer or a scattering layer is further provided in addition to the structure of FIG. 4 (a).

### DETAILED DESCRIPTION OF MAIN ELEMENTS

100: substrate
101: barrier layer
110: transparent electrode
120: photoelectrode
130: metal collector electrode
140: metal collector electrode protective layer
150: catalytic electrode
160: sealing material
170: electrolyte
170-1: electrolyte and insulating layer
200: solar cell panel
210: bonding material layer
220: adhesive member layer
300: first support
310: second support
320: protective coating layer
330: scattering layer

It should be understood that the appended drawings are not necessarily to scale, presenting a somewhat simplified representation of various preferred features illustrative of the basic principles of the invention. The specific design features of the invention as disclosed herein, including, for example, specific dimensions, orientations, locations and shapes, will be determined in part by the particular intended application and use environment. The specific solar cell type of the invention as disclosed herein will be determined in part by the particular intended application and use environment.

In the figures, reference numerals refer to the same or equivalent parts of the disclosure throughout the several figures of the drawings.

### DETAILED DESCRIPTION

Hereinafter, reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

The present invention provides a unified solar roof and glass structure in which a solar cell is built in a solar roof, including: a first support 300 and a second support 310; a dye-sensitized solar cell panel 200 disposed between the first and second supports 300, 310; and a bonding material layer 210 arranged for bonding and unifying the first and second supports 300, 310 with the solar cell panel 200 disposed between the first support 300 and the second support 310.

The first and second supports 300, 310 used in the present invention are usually the same, but may also be different from each other. According to various embodiments, the first and second supports 300, 310 may be formed of a transparent reinforced glass or a transparent polymer material. According to an exemplary embodiment, the first support 300 is formed of a reinforced glass and the second support 310 is formed of a reinforced glass, a general transparent glass or a transparent polymer material. As used herein, “transparent” refers to a state where visibility is guaranteed.

The solar roof structure according to the present invention has a structure where the glass portion of a sunroof or panorama roof (hereinafter, “sunroof”) is doubly paned similarly to the front windshield glass of a vehicle, and a solar cell panel 200 is laminated in the glass of the sunroof. Although the actual sunroof glass has curvatures R₁ and R₂, it is graphically represented as if it were planar for the sake of convenience. Specifically, the first support 300, which corresponds to the topmost sunroof glass in the drawings, may be formed of a reinforced glass such as a thermally reinforced glass or a chemically reinforced glass since it is exposed to the outside environment.

The second support 310 disposed therebelow may be formed of a reinforced glass or a commonly used glass (soda-lime glass, low-iron glass, alkali-free glass, etc.) or a polymer or plastic film. For example, one or more polymer materials selected from the group consisting of polyethylene, polypropylene, polyester, polyacryl, polyimide, polyamide, polystyrene, etc. and blends thereof, or copolymers or laminates of the polymer materials may be used. For example, polycarbonate (PC), polyethersulfone (PES), cyclic olefin copolymer (COC), polyethylene (PE), polyethylene terephthalate (PET), polyethylene naphthalate (PEN), triacetylcellulose (TAC), poly(methyl methacrylate) (PMMA), polyether ether ketone (PEEK), polyamide, polyimide (PI), polyetherimide (PEI), polypropylene (PP), oriented polypropylene (OPP), ethylene vinyl acetate (EVA), etc., and blends thereof may be used. The second support 310 may be coated with any material capable of protecting the solar cell panel 200, such as a resin mixed with a filler such as glass fiber, an organic/inorganic hybrid material, a ceramic, stainless steel, steel, etc. However, use of an opaque second support 310 is not recommended to ensure viewing through the sunroof.

The dye-sensitized solar cell panel 200 is inserted and disposed between the first and second supports 300, 310.

At present, a soda-lime glass is commonly used as the transparent substrate of a dye-sensitized solar cell panel. Since the substrate is usually at least 2 mm in thickness, a solar cell panel prepared therefrom has a thickness of at least 4 mm. Meanwhile, to ensure safety of passengers, the reinforced glass used for the automotive sunroof usually has a thickness of about 4 mm. Accordingly, if the solar cell fabricated according to the existing method is attached on the automotive sunroof, the total thickness becomes at least 8 mm. This may result in increased vehicle weight and decreased fuel efficiency. In addition, the increased sunroof thickness may interfere with the motion of the sunroof (e.g., when opening and closing) and may further result in reduced indoor space. This may require change in the design of the vehicle and increased costs. Accordingly, the solar cell panel used for a vehicle needs to be thin and lightweight.

The substrate of the solar cell panel 200 of the present invention may be formed of any of soda-lime glass, low-iron glass, alkali-free glass, etc. Depending on situations, a chemically reinforced glass, a doubly reinforced glass, a reinforced glass, a general glass, etc. may also be used. If the substrate is a glass, it is recommended to use a thin glass to ensure adequate indoor space and minimize weight increase. Accordingly, in an exemplary embodiment of the present invention, the glass used for the solar cell panel 200 has a thickness ranging from about 0.05 mm (ultra-thin glass) to several millimeters, specifically 4 mm, more specifically from about 0.1 to about 3 mm. However, the glass used for the solar cell panel is not being limited thereto.

In addition to glass, a plastic film may be used to decrease the thickness of the substrate of the solar cell panel 200. Specifically, a transparent material that transmits about 60% or more of visible light may be used.

That is to say, as the substrate material of the solar cell panel 200, a polymer material selected from the group consisting of polyethylene, polypropylene, polyester, polyacryl, polyimide, polyamide, polystyrene, etc., and blends thereof, copolymers and laminates thereof may be used. For example, polycarbonate (PC), polyethersulfone (PES), cyclic olefin copolymer (COC), polyethylene (PE), Polyethylene terephthalate (PET), polyethylene naphthalate (PEN), triacetylcellulose (TAC), poly(methyl methacrylate) (PMMA), polyether ether ketone (PEEK), polyamide, polyimide (PI), polyetherimide (PEI), polypropylene (PP), oriented polypropylene (OPP), etc. and blends thereof may be used. In addition to these specific materials, any transparent material that can be fabricated into a substrate may be used.

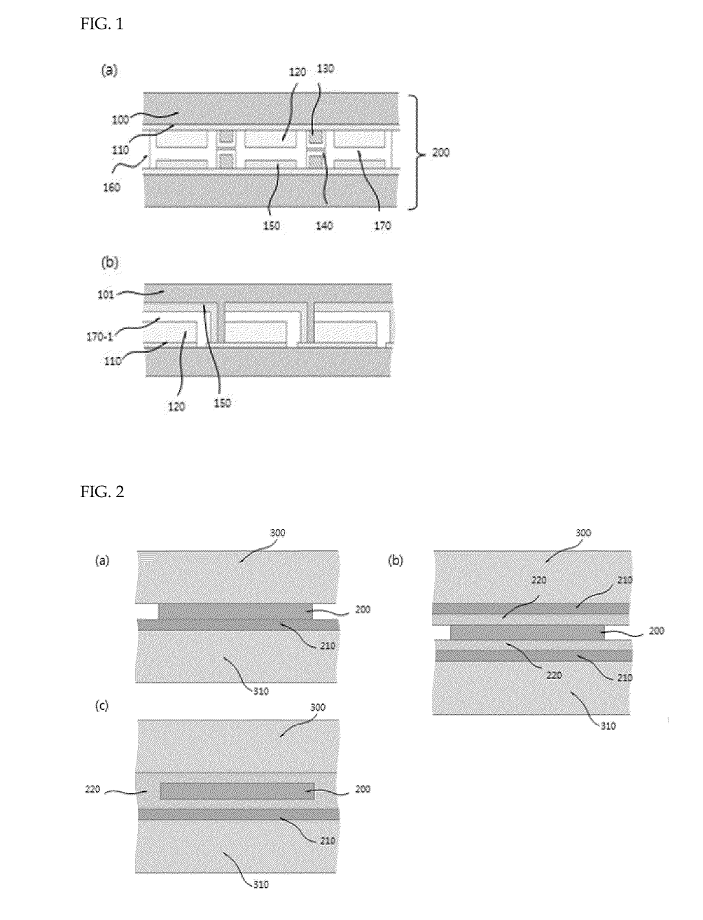

In an exemplary embodiment of the present invention, the dye-sensitized solar cell panel 200 has an exemplary structure as shown in FIG. 1.

According to various embodiments, the dye-sensitized solar cell panel 200 used in the present invention has a unit cell structure in which a working electrode is joined with a counter electrode. Inside the cell, a dye that absorbs light and emits an electron, a porous nanoparticulate semiconductor oxide that that transfers the emitted electron to an external electrode, an electrolyte that compensates for the electron emitted from the dye, and a counter electrode that reduces the oxidized electrolyte are provided. The working electrode and the counter electrode are coated with a transparent conducting oxide (TCO) layer, such as fluorine-doped tin oxide (FTO), so that the emitted photoelectron can move. As the solar cell becomes larger in size, current collecting efficiency decreases due to the resistance of the transparent conducting oxide layer. Usually, a metal electrode is further inserted in the solar cell panel 200 to compensate for this. Also, a collector electrode protective layer is often formed to prevent corrosion of the metal electrode by the electrolyte. In the present invention, a structure in which the metal collector electrode 130 is inserted will be called a module and a solar cell in which such modules are arranged in series or in parallel will be called a panel, for the sake of convenience. FIG. 1 shows cross-sectional views of a basic structure of the module. Although only a structure in which the cells are connected in parallel (a) and a monolithic structure (b) are shown in the figure, various structures such as a Z-type structure in which the cells are connected in series, a W-type structure in which a photoelectrode and a catalytic electrode are formed alternatingly on one substrate, or the like are also possible. As described, FIG. 1 (a) shows a parallel structure and FIG. 1 (b) shows a monolithic structure. Of the two, the monolithic structure is advantageous in terms of cost reduction, since only one substrate is used, although the performance is worse than other structures. In the present invention, the parallel structure shown in FIG. 1 (a) may be used. But without being limited thereto, any one applicable to a solar cell and other devices that can be mounted in a vehicle may be used.

In accordance with the present invention, the first and second supports 300, 310 are bonded to the solar cell panel 200 for unification using the bonding material layer 210.

The bonding material layer 210 used in the present invention serves to join the first and second supports 300, 310 and laminate the solar cell. The bonding material layer 210 may be formed of any material capable of bonding two transparent supports. For example, the bonding material layer 210 can be formed of one or more materials selected from the group consisting of polyvinyl butyrate (PVB) film and resin, EVA sheet and resin, polyolefin, ionomer film, polyvinyl alcohol, polyvinyl acetate, poly(methyl methacrylate) (PMMA), polyacryl, polystyrene (PS), styrene-based thermoplastic copolymers such as styrene-butadiene-styrene (SBS) block copolymer, styrene-isoprene-styrene (SIS) triblock copolymer, styrene-ethylene-butylene-styrene (SEBS) block copolymer, acrylonitrile-butadiene-styrene (ABS) copolymer, etc. and celluloses such as methyl cellulose, ethyl cellulose, butyl cellulose, etc., and blends thereof, that can be bonded by applying heat or pressure.

The bonding material layer 210 serves to fix the solar cell panel 200 to the supports 300, 310 and also plays an important role of preventing the broken pieces from harming passengers by capturing them, particularly if the solar cell panel 200 is used for an automotive sunroof and is broken, especially when the solar cell substrate is glass. Specifically, in order to ensure a view through the sunroof, a material that transmits at least about 60% of visible light is used among those described above.

The bonding material layer 210 according to the present invention may be a film having bonding layers formed on both sides of a polymer substrate. The polymer substrate may be a film formed of polydimethylsiloxane (PDMS), polysilazane, PSSQ (polysilsesquioxane), polysilicon, polyurethane, epoxy, synthetic rubber, natural rubber, modified elastomer, polyacryl such as poly(methyl methacrylate) (PMMA), etc., polyolefin, acryl, urethane, modified acryl and modified urethane, blends thereof, copolymers or laminates thereof. However, the bonding material layer 210 is not particularly limited to these materials. According to various embodiments, the bonding layers 210 formed on both sides of the substrate are formed of one or more materials selected from the group consisting of epoxy, acryl, urethane, modified acryl, modified urethane, modified elastomer and silicone, and are formed on both sides thereof.

The bonding material layer 210 may be formed on the upper first support 300, on the lower second support 310, or both. FIG. 2 (a) shows an example wherein the bonding material layer 210 is formed on the lower second support 300 only.

Exemplary embodiments of the solar roof structure unified with glass of the present invention will be described below. The specific embodiments of the present invention are schematically shown in FIGS. 2-5.

An exemplary embodiment of the present invention includes a structure in which a first support 300, a solar cell panel 200, a bonding material layer 210 and a second support 310 are sequentially laminated. Such a structure is shown in FIG. 2 (a). Specifically, FIG. 2 (a) shows a structure wherein a solar cell panel 200 is positioned on a first support 300 and a second support 310 having a bonding material layer 210 on the surface thereof. This structure provides a unified structure through bonding.

Another exemplary embodiment includes a structure in which a first support 300, a bonding material layer 210, a solar cell panel 200 and a second support 310 are sequentially laminated.

Another exemplary embodiment according to the present invention includes a solar roof structure unified with glass in which an adhesive member layer 220 is further included between the first and second supports 300, 310.

Specifically, the adhesive member layer 220 may be used to absorb impact and protect the solar cell. The adhesive member layer 220 may be formed of one or more materials selected from the group consisting of polydimethylsiloxane (PDMS), polysilazane, polysilsesquioxane (PSSQ), silicon, polyurethane, epoxy, synthetic rubber, natural rubber, modified elastomer, polyacryl such as poly(methyl methacrylate) (PMMA), etc., styrene-based thermoplastic copolymer such as polystyrene (PS), styrene-butadiene-styrene (SBS) block copolymer, styrene-isoprene-styrene (SIS) triblock copolymer, styrene-ethylene-butylene-styrene (SEBS) block copolymer, acrylonitrile-butadiene-styrene (ABS) copolymer, etc. and cellulose such as methyl cellulose, ethyl cellulose, butyl cellulose, etc., and blends thereof. Preferably, the adhesive member layer 220 may be formed of a material that retains flexibility and cushioning property after fabrication.

Another exemplary embodiment of the present invention includes a structure in which a first support 300, a bonding material layer 210, an adhesive member layer 220, a solar cell panel 200, another adhesive member layer 220, another bonding material layer 210 and a second support 30 are sequentially laminated. Specifically, FIG. 2 (b) shows such a structure wherein a bonding material layer 210, an adhesive member layer 220 and a solar cell panel 200 are positioned sequentially on a first support 300 and a second support 310 having an adhesive member layer 220 and a bonding material layer 210 laminated on the surface thereof, which is then unified through bonding.

Another exemplary embodiment of the present invention includes a structure wherein a first support 300, an adhesive member layer 220 in which a solar cell panel 200 is completely inserted and unified, a bonding material layer 210 and a second support 310 are sequentially laminated. Specifically, FIG. 2 (c) shows such a structure wherein an adhesive member layer 220 in which a solar cell panel 200 is completely inserted is disposed on a first support 300 and a second support 310 having a bonding material layer 210 on the surface thereof is unified through bonding.

In this exemplary embodiment, the bonding material layer 210 is disposed alone or together with the adhesive member layer 220 on both sides of the solar cell to provide protection from impact exerted from the top and bottom surfaces of the roof. The bonding material layer 210 is inserted between the adhesive member layer 220 and the two supports 300, 310 in contact therewith to provide bonding force. In this exemplary embodiment, the adhesive member layer 220 may be disposed at only one of the upper or lower side of the solar cell panel 200. Also, the bonding material layer 210 may be disposed at only one or at both of the first and second supports 300, 310. Further, the adhesive member layer 220 may have a bonding layer (not shown) formed on either or both sides of the adhesive member layer 220 to enhance bonding force with the solar cell panel 200 or the first and second supports 300, 310. If the bonding force is provided by the adhesive member layer 220, the bonding material layer 210 may be eliminated if desired.

The structures shown in FIG. 2 completely enclose the void that may be formed because of the thickness of the solar cell panel 200. For example, as shown in FIG. 2 (c), the adhesive member layer 220 has a space in which the solar cell panel 200 can be inserted such that it can be completely attached to the first and second supports 300, 310. The adhesive member layer 220 may be formed as one structural unit, or two adhesive member layers 200 formed as separate structural units may be disposed on the top and bottom of the solar cell panel 200 and then laminated. When two adhesive member layers 220 are used as described above, the layer contacting with the upper surface of the solar cell panel 200 may have an insertion space formed at the bottom surface of the solar cell panel 200 and the layer contacting the lower surface of the solar cell panel 200 may have an insertion space formed at the top surface thereof such that, when the two adhesive member layers 220 are laminated, the solar cell panel 200 is completely disposed or encased within the adhesive member layer 220. As described above, the bonding layer 210 may be formed on either or both sides of the adhesive member layer 220. The bonding material layer 210 may be formed on the upper side, lower side or both sides of the supports 300, 310.

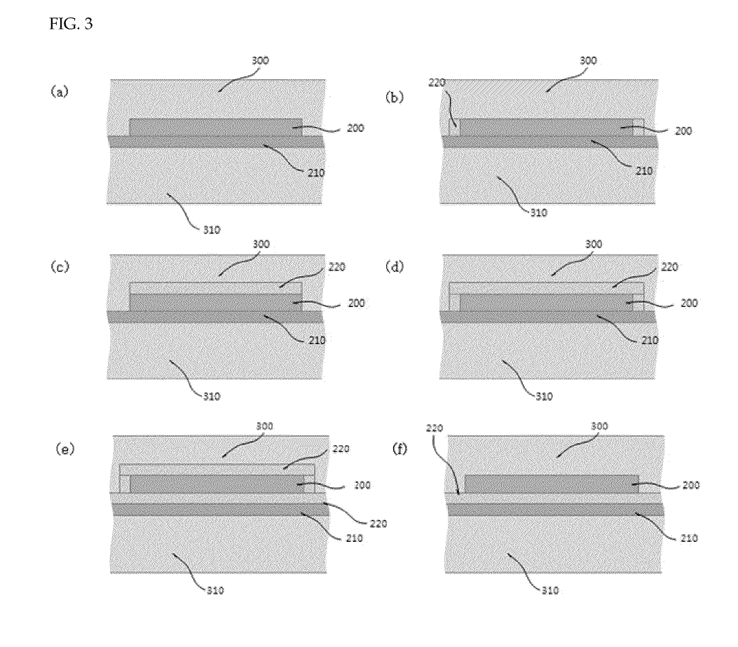

Another exemplary embodiment of the present invention includes a structure wherein a first support 300 having an insertion hole formed such that a solar cell panel 200 can be inserted without void, a solar cell panel 200 inserted in the insertion hole of the first support 300, a bonding material layer 210 and a second support 310 are sequentially laminated. For example, as shown in FIG. 3 (a), a solar cell panel 200 is completely inserted in an insertion hole (portion inside of which the solar cell panel 200 is disposed) of a first support 300 and a second support 310 having a bonding material layer 210 on the surface thereof is unified through bonding.

Another exemplary embodiment of the present invention includes a structure wherein a first support 300 having an insertion hole formed to have a width wider than that of a solar cell panel 200 and a depth corresponding to a thickness of the solar cell panel 200, a solar cell panel 200 inserted in the insertion hole of the first support 300, a bonding material layer 210, with an adhesive member layer 220 filled in a space formed by the first support 300 (i.e. in a portion of the insertion hole not filled by the solar cell panel 200 and the bonding material layer 210), and a second support 310 are sequentially laminated. Such a structure is shown in FIG. 3 (b).

Another exemplary embodiment of the present invention includes a structure wherein a first support 300 having an insertion hole formed to have a depth deeper than a thickness of a solar cell panel 200 and a width corresponding to that of the solar cell panel 200, a solar cell panel 200 inserted in the insertion hole of the first support, a bonding material layer 210, with an adhesive member 200 layer filled in a space formed by the first support 300 (i.e., in a portion of the insertion hole not filled by the solar cell panel 200 and the bonding material layer 210), and a second support 310 are sequentially laminated. Such a structure is shown in FIG. 3 (c).

Another exemplary embodiment of the present invention includes a structure wherein a first support 300 having an insertion hole formed to have a depth and a width larger than a thickness and a width of a solar cell panel 200, with an adhesive member layer 220 formed on the entire surface of the first support 300, a solar cell panel 200 inserted in the insertion hole to be parallel to the first support 300, a bonding material layer 210 and a second support 310 are sequentially laminated. Such a structure is shown in FIG. 3 (d).

Another exemplary embodiment of the present invention includes a structure wherein a first support 310 having an insertion hole formed to have a depth and a width larger than a thickness and a width of a solar cell panel 200, with an adhesive member layer 220 formed on the entire surface of the first support 300, a solar cell panel 200 inserted in the insertion hole to be parallel to the first support 200, an adhesive member layer 220 formed therebelow and a second support 310 are sequentially laminated. Such a structure is shown in FIG. 3 (e).

Another exemplary embodiment of the present invention includes a structure wherein a first support 300 having an insertion hole in which a solar cell panel 200 can be inserted without void, a solar cell panel 200 inserted in the insertion hole of the first support 300, a bonding material layer 210, an adhesive member layer 220 and a second support 310 are sequentially laminated. Such a structure is shown in FIG. 3 (f).

In the exemplary embodiments shown in FIG. 3, the first support 300 or the second support 310 is processed such that the solar cell panel 200 is inserted in the first or second support 300, 310. Although the solar cell panel 200 is inserted in the first support 300 in the drawings, it may also be inserted in the second support 310. The structures shown in FIG. 3 are advantageous in that the first and second supports 300, 310 can be completely adhered together. Further, a bonding material layer 210 may be formed between the two supports 300, 310 to enhance the bonding of the two supports 300, 310. In these structures, an adhesive member layer 220 may be formed at the portion where the solar cell panel 200 is contacted with the first and second supports 300, 310 so as to absorb external impact and enhance adhesion between the supports 300, 310 and the solar cell panel. A bonding layer 210 may be formed on either or both sides of the adhesive member layer 220. In the embodiments shown in FIGS. 3 (e) and (f), the bonding material layer 210 may be omitted if the bonding force is provided by the adhesive member layer 220.

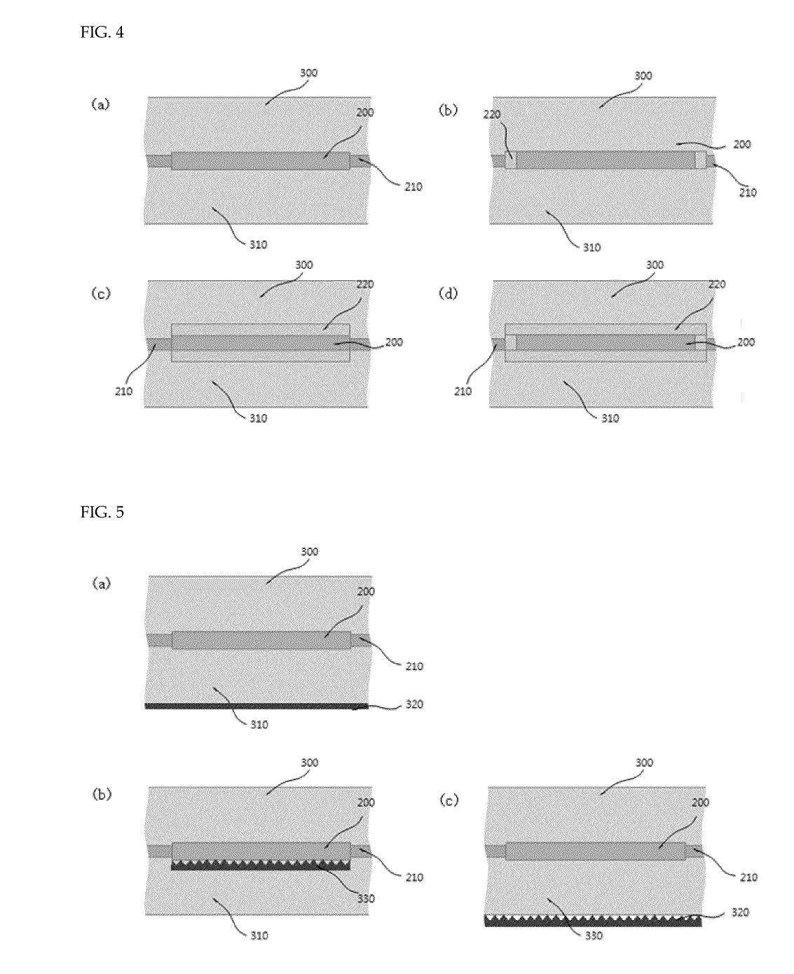

Another exemplary embodiment of the present invention includes a solar roof structure unified with glass wherein a first support 300 and a second support 310 each having an insertion hole with a depth smaller than a thickness of a solar cell panel 200 formed therein, such that the solar cell panel 200 can be inserted without a void, a solar cell panel 200 inserted in the insertion holes of the first and second supports 300, 310 and a bonding material layer 210 disposed in a space formed by the first and second supports 300, 310 (i.e., in a portion of the insertion holes not filled by the solar cell panel 200) are laminated. Such a structure is shown in FIG. 4 (a).

Another exemplary embodiment of the present invention includes a structure which includes a first support 300 and a second support 310 each having an insertion hole with a width wider than that of a solar cell panel 200 and a depth smaller than a thickness of the solar cell panel 200 formed such that the solar cell panel 200 can be inserted to be unified at the left and right sides, a solar cell panel 200 inserted in the insertion holes of the first and second supports 300, 310, a bonding material layer 210 formed between the first and second supports 300, 310 and an adhesive member layer 220 filled in a space formed by the first and second supports 300, 310 (i.e., in a portion of the insertion holes not filled by the solar cell panel 200 and the bonding material layer 210. Such a structure is shown in FIG. 4 (b).

Another exemplary embodiment of the present invention includes a structure which includes a first support 300 and a second support 310 each having an insertion hole with a width corresponding to that of a solar cell panel 200, an adhesive member layer 220 formed on the first and second supports 300, 310 except for the side where the insertion holes are formed, a solar cell panel 200 formed between the adhesive member layers 220 of the first and second supports 300, 310 and inserted in the insertion holes of the first and second supports 300, 310 and a bonding material layer 210 formed between the first and second supports 300, 310. Such a structure is shown in FIG. 4 (c).

Another exemplary embodiment of the present invention includes a structure which includes a first support 300 and a second support 310 each having an insertion hole with a depth and a width larger than a thickness and a width of a solar cell panel 200, an adhesive member layer 220 coated on the entire surface of the insertion holes of the first and second supports 300, 310, a solar cell panel 200 inserted in the insertion holes of the first and second supports 300, 310 having the adhesive member layer 220 and a bonding material layer 210 formed between the first and second supports 300, 310. Such a structure is shown in FIG. 4 (d).

The structures shown in FIG. 4 are basically similar to those shown in FIG. 3. Both the first and second supports 300, 310 can be processed such that the solar cell panel 200 is inserted in the insertion holes between the two supports 300, 310. If the insertion hole is formed on only one support 300 or 310 as in the embodiments shown in FIG. 3, the depth of the insertion hole should vary depending on the thickness of the solar cell panel 200. If the solar cell panel 200 has a large thickness, the insertion hole should be formed deep. This may decrease the strength of the support. If both the first and second supports 300, 310 are processed, the depth of each insertion hole to be processed is decreased to ½ and, hence, the decrease of strength can be reduced.

In another exemplary embodiment, the solar roof structure unified with glass of the present invention may further include a protective coating layer 320, a scattering layer 330 or both.

A specific example includes a structure wherein a protective coating layer 320 is further formed on an outer surface of the second support 310 of the structure shown in FIG. 4 (a), which includes the first support 300 and the second support 310 each having the insertion hole with a depth smaller than a thickness of a solar cell panel 200 formed therein such that the solar cell panel 200 can be inserted without void, the solar cell panel 200 inserted in the insertion holes of the first and second supports 300, 310 and the bonding material layer 210 disposed in a space formed by the first and second supports 300, 310 and the solar cell panel 200. Such a structure is shown in FIG. 5 (a).

Another example includes a structure wherein a scattering layer 330 is further formed between the solar cell panel 200 and the second support 310 of the structure shown in FIG. 4 (a), which includes the first support 300 and the second support 310 each having the insertion hole with a depth smaller than a thickness of a solar cell panel 200 formed therein such that the solar cell panel 200 can be inserted without void, the solar cell panel 200 inserted in the insertion holes of the first and second supports 300, 310 and the bonding material layer 210 disposed in a space formed by the first and second supports 300, 310 and the solar cell panel 200. Such a structure is shown in FIG. 5 (b).

Another example includes a structure wherein a scattering layer 330 further formed on an outer surface of the second support 310 of the structure shown in FIG. 4 (a), which includes the first support 300 and the second support 310 each having the insertion hole with a depth smaller than a thickness of a solar cell panel 200 formed therein such that the solar cell panel 200 can be inserted without void, the solar cell panel 200 inserted in the insertion holes of the first and second supports 300, 310 and the bonding material layer 210 is disposed in a space formed by the first and second supports 300, 310 and the solar cell panel 200. Such a structure is shown in FIG. 5 (c).

In the embodiments shown in FIG. 5, a thermally curable or photocurable protective coating layer 320 may be formed on the side of the second support 310 exposed to the inside of a vehicle in order to confer, for example, scratch resistance and enhance surface strength. FIG. 5 (a) shows such an example wherein a protective coating layer 320 is further formed in the structure of FIG. 4 (a). Also, a scattering layer 330 may be formed on one side of the counter electrode of the solar cell panel 200 so as to reduce loss of incident light to outside by scattering the light inside the solar cell and, thus, to improve solar cell efficiency. The scattering layer 330 may also be formed on the support. FIGS. 5 (b) and (c) show such examples wherein a scattering layer 330 is further formed in the structure of FIG. 4 (a).

The scattering layer 330 may be prepared, for example, by forming unevenness, such as triangular unevenness, on the surface of a polymer base film or by introducing organic or inorganic beads of different sizes on the base film using an adhesive layer. However, these are only exemplary and any variety of scattering layer configurations prepared by commonly employed methods may be used. The film used to prepare the scattering layer 330 may be selected from any that are commonly used in display products including, for example, anti-reflection (AR) film, anti-glare (AG) film, low-reflection (LR) film, diffusion film, etc. Although not shown in the figures, a film increasing light transmittance (e.g., AR, AG or LR) may be further provided between the first support 300 and the solar cell panel 200 or on the outer surface of the first support 300. Also, the same effect may be achieved by introducing a film on which a light-reflecting layer, e.g., aluminum foil, mirror, etc., is formed as a scattering layer 330. However, since the aluminum foil, mirror, etc. may result in poor lighting when used, for example, in an automotive sunroof, use thereof is not recommended on the parts where lighting is important. The scattering layer 330 may be introduced to any of the afore-described embodiments.

The present invention also includes the structures wherein a commonly used low-reflection film is formed between the first support 300 and the solar cell panel 200 or on the outer surface of the first support 300.

In the present invention, an anti-UV film or glass may be provided to prevent the material of the solar cell panel 200 from being discolored or damaged upon exposure to external environment. The anti-UV film or glass may be introduced to any of the afore-described embodiments and may be disposed on the working electrode of the solar cell panel or any other part. For example, it may be disposed on the upper or lower surface of the reinforced glass used as the first or second support 300, 310 or on the working electrode of the solar cell panel 200, without being limited thereto. Considering that the dye included in the solar cell panel 200 may be desorbed by UV, use of the anti-UV film is recommended.

The solar roof structure unified with glass according to the present invention is applicable to an automotive sunroof or a panorama roof, and the present invention further provides an automotive sunroof and an automotive panorama roof wherein the structure of the present invention is included.

Use of the solar roof structures unified with glass described in the embodiments of the present invention allows the device, such as the solar cell, to be mounted on the top surface of a vehicle, especially integrally with a sunroof or a panorama roof. As a result, the opacity problem of the existing silicon solar cell can be solved while ensuring viewing through the sunroof and providing various colors.

Further, by reducing the thickness of the solar cell panel 200, the solar roof can be made thinner and lighter. In addition, the use of the adhesive member protects the solar cell panel from external impact. Especially, when the panel is broken due to a strong external impact, the structure of the present invention prevents the broken pieces from harming passengers by capturing them.

In addition, if the solar cell of the present invention is mounted on a vehicle, the power generated by the solar cell may be used in a variety of ways, such as to lower the temperature in the passenger compartment which has risen during parking, or to operate some electrical parts of the vehicle, such as air-conditioning system, cluster ionizer, etc. without power supply. Further, for an HEV or EV, additional mileage can be provided through battery recharging.

A test was performed to demonstrate the effect of the present invention.

Table 1 shows a simulation test result of measuring maximum stress exerted on a solar cell panel from an external impact when an adhesive member was used as shown in FIG. 2 (b). As demonstrated in Table 1, the maximum stress exerted on the solar cell panel from an external impact was decreased when the adhesive member was used. A reinforced glass was used as the first support and a protective film was used for the second support. A soda-lime glass was used as the substrate of the solar cell panel. Considering that the glass was broken when a stress exceeded 50 MPa, the present invention provides a panel-protecting effect.

TABLE 1

| | Test result |
|---|---|
| Presence of | Stress exerted on |
| Adhesive member | solar cell panel (MPa) |
| NO | 178.6 |
| YES | 46.3 |

As described above, the solar roof structure unified with glass according to the present invention, which is thin and lightweight, ensures safety while providing viewing therethrough. Accordingly, when it is used, for example, in an automotive sunroof, it can provide good vision and can provide passenger safety even if it is broken due to external impact.

Further, the structure can be fabricated easily, can have various colors, is thin and lightweight, can generate electrical power and can provide superior physical properties.

The present invention has been described in detail with reference to specific embodiments thereof. However, it will be appreciated by those skilled in the art that various changes and modifications may be made in these embodiments without departing from the principles and spirit of the invention, the scope of which is defined in the appended claims and their equivalents.

What is claimed is:

1. A solar roof structure unified with glass in which a solar cell is built in a solar roof, comprising:
a first support and a second support, each comprising a transparent reinforced glass or a transparent polymer material;
a solar cell selected from a dye-sensitized solar cell, a organic photovoltaic cell, a crystalline silicon solar cell, an amorphous silicon solar cell, and a thin film solar cell disposed between the first and second supports; and
a bonding material layer disposed to bond and unify the first and second supports with the solar cell panel disposed between the first support and the second support.

2. The solar roof structure according to claim 1, wherein the bonding material layer comprises one or more selected from a group consisting of polyvinyl butyrate (PVB) film and resin, EVA sheet and resin, polyolefin, ionomer film, polyvinyl alcohol, polyvinyl acetate, poly(methyl methacrylate) (PMMA), polyacryl, polystyrene (PS), styrene-butadiene-styrene (SBS) block copolymer, styrene-isoprene-styrene (SIS) triblock copolymer, styrene-ethylene-butylene-styrene (SEBS) block copolymer, acrylonitrile-butadiene-styrene (ABS) copolymer, methyl cellulose, ethyl cellulose and butyl cellulose.

3. The solar roof structure according to claim 1, wherein the bonding material layer is a polymer substrate comprising one or more selected from the group consisting of polydimethylsiloxane (PDMS), polysilazane, PSSQ (polysilsesquioxane), polysilicon, polyurethane, epoxy, synthetic rubber, natural rubber, modified elastomer, polyacryl such as poly(methyl methacrylate) (PMMA), etc., polyolefin, acryl, urethane, modified acryl and modified urethane or a blend, copolymer or laminate thereof having bonding layers comprising one or more selected from epoxy, acryl, urethane, modified acryl, modified urethane, modified elastomer and silicone, formed on both sides thereof.

4. The solar roof structure according to claim 1, wherein the first support, the solar cell panel, the bonding material layer and the second support are sequentially laminated.

5. The solar roof structure according to claim 1, wherein the first support, the bonding material layer, the solar cell panel and the second support are sequentially laminated.

6. The solar roof structure according to claim 1, wherein an adhesive member layer is further disposed between the first and second supports.

7. The solar roof structure according to claim 6, wherein the adhesive member layer comprises one or more selected from the group consisting of polydimethylsiloxane (PDMS), polysilazane, PSSQ (polysilsesquioxane), silicon, polyurethane, epoxy, synthetic rubber, natural rubber, modified elastomer, poly(methyl methacrylate) (PMMA), polystyrene (PS), styrene-butadiene-styrene (SBS) block copolymer, styrene-isoprene-styrene (SIS) triblock copolymer, styrene-ethylene-butylene-styrene (SEBS) block copolymer, acrylonitrile-butadiene-styrene (ABS) copolymer, methyl cellulose, ethyl cellulose and butyl cellulose.

8. The solar roof structure according to claim 6, wherein the first support, the bonding material layer, the adhesive member layer, the solar cell panel, a second adhesive member layer, a second bonding material layer and the second support are sequentially laminated.

9. The solar roof structure according to claim 6, wherein the first support, the adhesive member layer in which a solar cell panel is completely inserted and unified, the bonding material layer and the second support are sequentially laminated.

10. The solar roof structure according to claim 1, wherein a first support having an insertion hole formed therein such that a solar cell panel is insertable therein without void, the solar cell panel inserted in the insertion hole, the bonding material layer and the second support are sequentially laminated.

11. The solar roof structure according to claim 6, wherein the first support having an insertion hole with a width wider than that of the solar cell panel and a depth corresponding to a thickness of the solar cell panel, the solar cell panel inserted in the insertion hole, the bonding material layer, the adhesive member layer filled in a space formed by the first support not filled by the solar cell panel and the bonding material layer, and the second support are sequentially laminated.

12. The solar roof structure according to claim 6, wherein the first support having an insertion hole with a depth deeper than a thickness of the solar cell panel and a width corresponding to that of the solar cell panel, the solar cell panel inserted in the insertion hole, the bonding material layer, the adhesive member layer filled in a space formed by the first support not filled by the solar cell panel and the bonding material layer, and the second support are sequentially laminated.

13. The solar roof structure according to claim 6, wherein the first support having an insertion hole with a depth and a width larger than a thickness and a width of the solar cell panel, the adhesive member layer formed on an entire surface of the first support, the solar cell panel inserted in the insertion hole parallel to the first support, the bonding material layer and the second support are sequentially laminated.

14. The solar roof structure according to claim 6, wherein the first support having an insertion hole with a depth and a width larger than a thickness and a width of the solar cell panel, the adhesive member layer formed on an entire surface of the first support, the solar cell panel inserted in the insertion hole parallel to the first support, the adhesive member layer formed therebelow and the second support are sequentially laminated.

15. The solar roof structure according to claim 6, wherein the first support having an insertion hole in which a solar cell panel is insertable without void, the solar cell panel inserted in the insertion hole, the bonding material layer, the adhesive member layer and the second support are sequentially laminated.

16. The solar roof structure according to claim 1, which comprises the first support and the second support, each of the first support and a second support having an insertion hole with a depth smaller than a thickness of the solar cell panel such that the solar cell panel can be inserted therein without void, the solar cell panel inserted in the insertion holes of the first and second supports, and the bonding material layer disposed in a space formed by the first and second supports and the solar cell panel.

17. The solar roof structure according to claim 6, which comprises the first support and the second support each having an insertion hole with a width wider than that of the solar cell panel and a depth smaller than a thickness of the solar cell panel formed such that the solar cell panel is insertable to be unified at left and right sides, the solar cell panel inserted in the insertion holes of the first and second supports, the bonding material layer formed between the first and second supports and the adhesive member layer filled in a space formed by the first and second supports, the solar cell panel and the bonding material layer.

18. The solar roof structure according to claim 6, which comprises the first support and the second support each having an insertion hole with a width corresponding to that of the solar cell panel, the adhesive member layer formed on the first and second supports except for a side where the insertion holes are formed, the solar cell panel formed between the adhesive member layers of the first and second supports and inserted in the insertion holes of the first and second supports and the bonding material layer formed between the first and second supports.

19. The solar roof structure according to claim 6, which comprises the first support and the second support each having an insertion hole with a depth and a width larger than a thickness and a width of the solar cell panel, the adhesive member layer coated on an entire surface of the insertion holes of the first and second supports, the solar cell panel inserted in the insertion holes of the first and second supports having the adhesive member layer and the bonding material layer formed between the first and second supports.

20. The solar roof structure according to claim 16, wherein a protective coating layer is further formed on an outer surface of the second support.

21. The solar roof structure according to claim 16, wherein a scattering layer is formed between the solar cell panel and the second support.

22. The solar roof structure according to claim 16, wherein a scattering layer is formed on an outer surface of the second support.

23. The solar roof structure according to claim 16, wherein a low-reflection film is formed between the first support and the solar cell panel or on an outer surface of the first support.

24. An automotive sunroof comprising the solar roof structure unified with glass according to claim 1.

25. An automotive panorama roof comprising the solar roof structure unified with glass according to claim 1.
